(19) United States
(12) Patent Application Publication
(10) Pub. No.: US 2021/0320059 A1
(43) Pub. Date: Oct. 14, 2021

(54) HYBRID BACK-END-OF-LINE (BEOL) DIELECTRIC FOR HIGH CAPACITANCE DENSITY METAL-OXIDE-METAL (MOM) CAPACITOR

(71) Applicant: QUALCOMM Incorporated, San Diego, CA (US)

(72) Inventors: Ye LU, San Diego, CA (US); John Jianhong ZHU, San Diego, CA (US); Lixin GE, San Diego, CA (US)

(21) Appl. No.: 16/846,591

(22) Filed: Apr. 13, 2020

(51) Int. Cl. H01L 23/522; H01L 49/02; H01L 23/528

(52) U.S. Cl. CPC H01L 23/5223; H01L 23/528; H01L 28/87

(57) ABSTRACT

Certain aspects of the present disclosure generally relate to a hybrid back-end-of-line (BEOL) dielectric for a high capacitance density metal-oxide-metal (MOM) capacitor, especially in lower BEOL layers. One example semiconductor device includes an active layer and a first metal layer disposed above the active layer. The first metal layer generally includes: a first electrode; a second electrode, wherein the first and second electrodes have interdigitated fingers; a first dielectric material disposed at least partially between at least two adjacent fingers of the first and second electrodes; and a second dielectric material, wherein the second dielectric material is different from the first dielectric material and wherein the first electrode, the second electrode, and the first dielectric material compose a portion of a metal-oxide-metal (MOM) capacitor.

### BACKGROUND

### Field of the Disclosure

Certain aspects of the present disclosure generally relate to semiconductor devices and, more particularly, to a hybrid back-end-of-line (BEOL) dielectric for a high capacitance density metal-oxide-metal (MOM) capacitor, especially in lower BEOL layers.

### Description of Related Art

A continued emphasis in semiconductor technology is to create improved performance semiconductor devices at competitive prices. This emphasis over the years has resulted in extreme miniaturization of semiconductor devices, made possible by continued advances in semiconductor processes and materials in combination with new and sophisticated device designs. Large numbers of transistors are employed in integrated circuits (ICs) in many electronic devices. For example, components such as central processing units (CPUs), graphics processing units (GPUs), and memory systems each employ a large quantity of transistors for logic circuits and memory devices. The ICs may include various layers of conductors (e.g., metal layers) disposed between layers of dielectric material, which are formed during a back-end-of-line (BEOL) fabrication process. The conductors facilitate electrical wiring between various electrical components including transistors, amplifiers, inverters, control logic, memory, power management circuits, buffers, filters, resonators, capacitors, inductors, resistors, etc. The conductors may also be used to create certain structures, such as metal-oxide-metal (MOM) capacitors.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include increasing metal-oxide-metal (MOM) capacitor capacitive density without increasing regular routing parasitic capacitance.

Certain aspects of the present disclosure provide a semiconductor device. The semiconductor device includes an active layer and a first metal layer disposed above the active layer. The first metal layer generally includes a first electrode; a second electrode, wherein the first and second electrodes have interdigitated fingers; a first dielectric material disposed at least partially between at least two adjacent fingers of the first and second electrodes; and a second dielectric material, wherein the second dielectric material is different from the first dielectric material and wherein the first electrode, the second electrode, and the first dielectric material compose a portion of a metal-oxide-metal (MOM) capacitor.

Certain aspects of the present disclosure provide a method for fabricating a semiconductor device. The method generally forming an active layer and forming a first metal layer above the active layer. The first metal layer generally includes a first electrode; a second electrode, wherein the first and second electrodes have interdigitated fingers; a first dielectric material disposed at least partially between at least two adjacent fingers of the first and second electrodes; and a second dielectric material, wherein: the second dielectric material is different from the first dielectric material; and the first electrode, the second electrode, and the first dielectric material compose a portion of a metal-oxide-metal (MOM) capacitor.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a cross-sectional view of an example semiconductor device.

FIG. 2 depicts an example metal-oxide-metal (MOM) capacitor.

FIG. 3A is a cross-sectional view of metal layers for a semiconductor device, including a MOM capacitor with a homogeneous dielectric.

FIGS. 3B-3E are cross-sectional views of metal layers for semiconductor devices, including various MOM capacitors with hybrid dielectrics, in accordance with certain aspects of the present disclosure.

FIGS. 4A-4G illustrate example operations for fabricating metal layers, including a MOM capacitor with a hybrid dielectric, in accordance with certain aspects of the present disclosure.

FIG. 5 is a flow diagram of example operations to fabricate a semiconductor device, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to a hybrid back-end-of-line (BEOL) dielectric for a high capacitance density metal-oxide-metal (MOM) capacitor, especially in lower BEOL layers of a semiconductor device, and methods for fabricating the same. With one dielectric material disposed in-between the metal fingers of a MOM capacitor and a different dielectric material disposed in-between the metal routing lines on the same metal layer and in the dielectric layers, the capacitance and capacitance density of a MOM capacitor may be increased, without increasing regular routing parasitic capacitance.

### Example Semiconductor Device

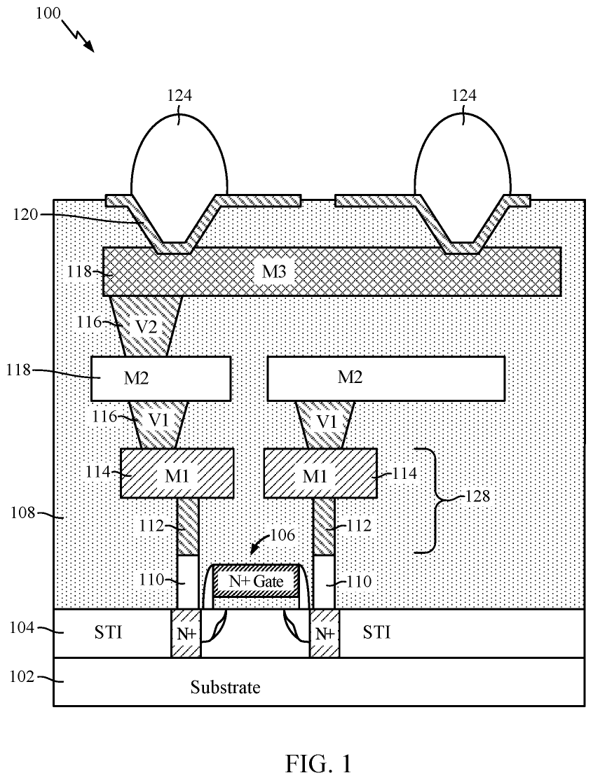

FIG. 1 is a cross-sectional view of an example semiconductor device 100, in which certain aspects of the present disclosure may be practiced. As shown, the semiconductor device 100 may include a substrate 102, a dielectric region 104, an active electrical device 106 (e.g., a transistor), dielectric layers 108, local conductive interconnects 110 (e.g., source-drain conductive contacts, which are often abbreviated as CA), first conductive vias 112, and a first layer of conductive traces 114 (e.g., metal layer one M1). In certain aspects, the semiconductor device 100 may include additional layers of conductive vias 116 (e.g., via layer one V1 and via layer two V2), additional layers of conductive traces 118 (e.g., metal layer two M2 and metal layer three M3), under-bump conductive pads 120, and solder bumps 124.

The substrate 102 may be, for example, a portion of a semiconductor wafer, such as a silicon wafer. The dielectric region 104 may be disposed above the substrate 102. The dielectric region 104 may comprise an oxide, such as silicon dioxide (SiO₂). In aspects, the dielectric region 104 may be a shallow trench isolation (STI) region configured to electrically isolate the active electrical device 106 from other electrical components, such as other electrical devices.

The active electrical device 106 may be disposed above the substrate 102. In this example, the active electrical device 106 may include one or more transistors, such as metal-oxide-semiconductor field-effect transistors (MOSFETs). In aspects, the MOSFETs may include fin field-effect transistors (finFETs) and/or gate-all-around (GAA) FETs. In certain aspects, the active electrical device 106 may be an inverter, amplifier, and/or other suitable electrical devices comprising transistors. The local conductive interconnects 110 may be electrically coupled to the active electrical device 106. For example, the source and/or drain of the active electrical device 106 may be electrically coupled to the local conductive interconnects 110, which are electrically coupled to the first conductive vias 112. In certain aspects, the active electrical device 106 (and the local interconnects 110) may be formed during a front-end-of-line (FEOL) fabrication process.

The first conductive via 112, additional conductive vias 116, and layers of conductive traces 114, 118 may be disposed above electrical components (e.g., the active electrical device 106) and formed during a back-end-of-line (BEOL) fabrication process of the semiconductor device 100. In aspects, the first conductive via 112, additional conductive vias 116, and layers of conductive traces 114, 118 may be embedded in the dielectric layers 108. The dielectric layers 108 may comprise an oxide, such as silicon dioxide. The first conductive vias 112, additional conductive vias 116, and layers of conductive traces 114, 118 provide electrical routing between the active electrical device 106 and other electrical components (not shown), including, for example, capacitors, inductors, resistors, an integrated passive device, a power management integrated circuit (PMIC), a memory chip, etc.

In this example, the semiconductor device 100 may be a flip-chip ball grid array (FC-BGA) integrated circuit having multiple solder bumps 124 electrically coupled to the under-bump conductive pads 120. In certain cases, the semiconductor device 100 may have conductive pillars (e.g., copper (Cu) pillars) that electrically couple the semiconductor device 100 to a package substrate, an interposer, or a circuit board, for example.

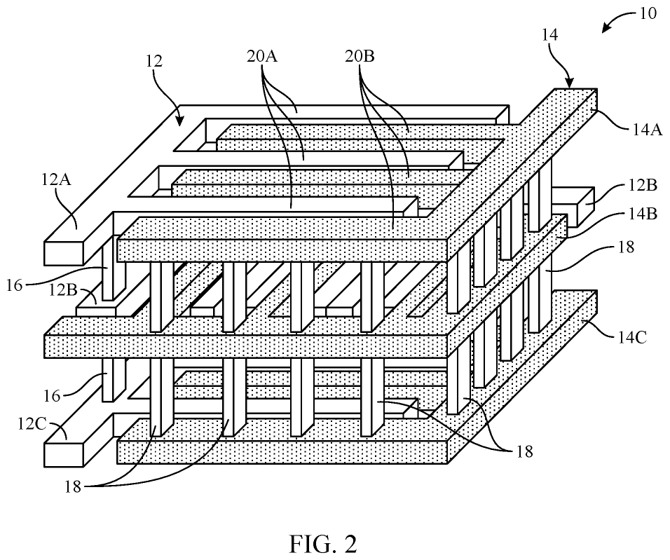

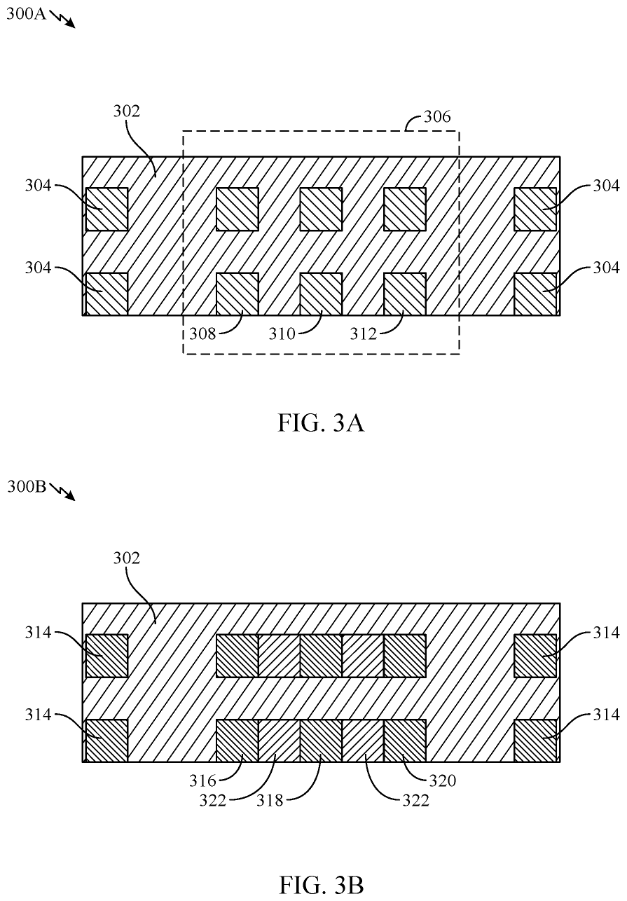

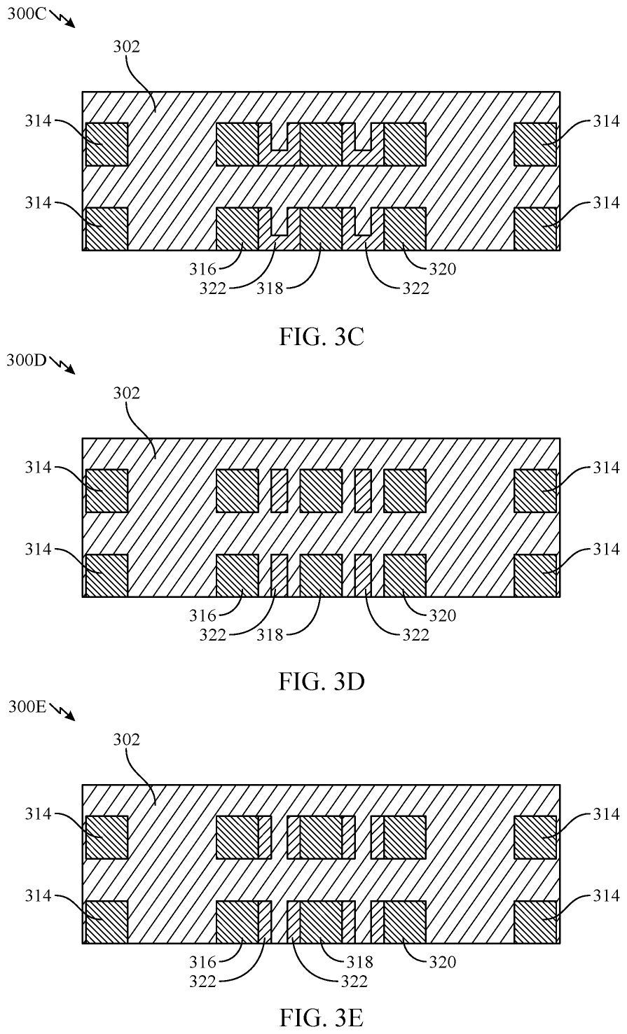

In certain aspects, the first layer of conductive traces 114 and/or one or more of the additional layers of conductive traces 118 may each implement a layer of a MOM capacitor, described herein with respect to FIGS. 2 and 3A-3E. The conductive traces (e.g., in M1, M2, and M3) implementing fingers of the MOM capacitor on any one metal layer may be electrically isolated from one another by a portion of the one or more dielectric layers 108 disposed between the conductive traces.

### Example MOM Capacitors

MOM capacitors are passive devices, which may be utilized in advanced logic or radio frequency (RF) circuits. MOM capacitors exploit the effect of lateral (or intra-layer) capacitive coupling between the plates formed by standard metallization wiring lines. Lateral capacitive coupling may provide better matching characteristics than vertical coupling due to a better process control of lateral dimensions than that of metal and dielectric layer thicknesses. To increase the capacitive density (capacitance per unit area of silicon chip), several metal layers are connected in parallel by vias, forming a vertical metal wall or mesh. Normally, the lowest metal layers with minimum metal line width and spacing are used for MOMs to maximize the capacitance density.

FIG. 2 depicts an example metal-oxide-metal (MOM) capacitor 10, in which certain aspects of the present disclosure may be practiced. The MOM capacitor 10 has an interdigitated double patterning structure with metal fingers interdigitated. The existence of these fingers causes the MOM capacitor 10 to also be referred to as a finger metal-oxide-metal capacitor (FMOM). As used herein, the term “finger” refers to the generally rectilinear element of a node that is interdigitated with other similar generally rectilinear elements. The MOM capacitor 10 is formed from two nodes. The first node of the MOM capacitor 10 is a first conductive element 12 (formed from elements 12A, 12B, and 12C). The second node of the MOM capacitor 10 is a second conductive element 14 (formed from elements 14A, 14B, and 14C). The various elements 12A, 12B, and 12C of first conductive element 12 are electrically coupled to one another with vias 16. Similarly, the various elements 14A, 14B, and 14C of second conductive element 14 are electrically coupled to one another with vias 18. Each of the elements 12A, 12B, and 12C includes a first set of metal fingers 20A. Similarly, each of the elements 14A, 14B, and 14C includes a second set of metal fingers 20B, which, as shown, are interdigitated with the metal fingers 20A of the elements 12A, 12B, and 12C.

As illustrated in FIG. 2, the elements 12A, 12B, and 12C are vertically stacked relative to one another. The elements 12A, 12B, and 12C are also designed to be directly disposed over one another so that the vias 16 are aligned. The elements 12A and 14A are disposed in a first metal layer, the elements 12B and 14B are disposed in a second metal layer arranged below the first metal layer, and the elements 12C and 14C are disposed in a third metal layer arranged below the second metal layer. It should be appreciated that the layers in the MOM capacitor 10 may be rotated ninety degrees relative to adjacent layers. That is, the first metal layer with elements 12A and 14A may be rotated ninety degrees relative to the second metal layer with elements 12B and 14B, which may be rotated ninety degrees relative to the third metal layer with elements 12C and 14C.

FIG. 3A is a cross-sectional view of metal layers 300A for a device. The metal layers 300A may represent lower BEOL layers (e.g., M1, M2, and/or M3) in a semiconductor device, for example. As illustrated, the metal layers 300A may include a dielectric material 302, routing metal lines 304, and a MOM capacitor 306.

The dielectric material 302 may surround the routing metal lines 304 and at least a portion of the MOM capacitor 306. The dielectric material 302 may comprise any of various suitable dielectric materials, such as silicon dioxide. Additionally, the dielectric material 302 may have a relatively low dielectric constant (κ) (e.g., κ32 3.5). Having a relatively low dielectric constant may result in a relatively low capacitive density, which may be inadequate for certain applications demanding higher capacitive density, as explained below.

The routing metal lines 304 may be arranged on either side of the MOM capacitor 306. Furthermore, the routing metal lines 304 may be disposed within the dielectric material 302 and be disposed in at least one row. Each row may represent a different metal layer of the device. In certain aspects, the routing metal lines 304 may be composed of copper (Cu). Additionally, if the routing metal lines 304 are composed of Cu, the routing metal lines 304 may include a barrier layer. Therefore, the fabrication process for the metal layers 300A may involve Cu patterning on the dielectric material 302.

The MOM capacitor may include at least one row of metal lines 308, 310, and 312, where each of the metal lines 308, 310, and 312 in FIG. 3A represents a cross-section of a finger of the MOM capacitor. Metal lines 308 and 310 may be disposed separated from one another with the dielectric material 302 filling at least a portion of the space between metal lines 308 and 310. The same can be said of metal lines 310 and 312. Additionally, metal lines 308 and 312 may be coupled to one electrode, while metal line 310 is coupled to another electrode different than the electrode coupled to metal lines 308 and 312. In this manner, a capacitance may be generated between metal lines 308 and 310, and a capacitance may be generated between metal lines 310 and 312.

Although only two rows of metal lines (e.g., two metal layers) are illustrated in FIG. 3A, it is to be understood that a device may include more than two metal layers. Furthermore, although the MOM capacitor 306 is illustrated as having one electrode with two fingers and another electrode with one finger, it is to be understood that a MOM capacitor may have any number of fingers for each electrode.

### Example MOM Capacitors with Hybrid Dielectrics

In advanced complementary metal-oxide-semiconductor (CMOS) technologies, for example, dielectric materials in lower back-end-of-line (BEOL) layers may commonly have low, or even extremely low, dielectric constants. As a consequence, a metal-oxide-metal (MOM) capacitor occupying one or more lower metal layer may have a low capacitive density, which may not be suitable for certain applications demanding higher capacitive density from such MOM capacitors.

Accordingly, certain aspects of the present disclosure provide a MOM capacitor with a hybrid dielectric for relatively higher capacitance density. Furthermore, for certain aspects, stable metals such as cobalt (Co) or ruthenium (Ru), which do not involve using a barrier layer, may be used to implement at least the lower BEOL metal layers.

FIG. 3B is a cross-sectional view of metal layers 300B for a device, in accordance with certain aspects of the present disclosure. The metal layers 300A may represent lower BEOL layers (e.g., M1, M2, and/or M3) in a semiconductor device, for example. When compared with reference to FIG. 3A, metal layers 300B may be somewhat similar in construction. However, metal layers 300B may include metal lines 314, which may be composed of cobalt (Co), ruthenium (Ru), or the like, as opposed to copper (Cu). Similarly, the MOM capacitor 306 may include at least one row of metal lines 316, 318, and 320, where each of the metal lines 316, 318, and 320 in FIG. 3B represents a cross-section of a finger of the MOM capacitor. By implementing the metal lines 314 and the metal lines 316, 318, and 320 with Co or Ru instead of Cu, a barrier layer need not be used.

Furthermore, using Co, Ru, or any other metal not needing a barrier layer for the metal lines 314 and the metal lines 316, 318, and 320 may enable implementing a combination of different dielectric materials (referred to herein as a “hybrid dielectric”) in the same metal layer. As shown, a dielectric material 322 may be disposed between the metal lines 316, 318, and 320 of the MOM capacitor 306 within each row (e.g., each metal layer). The dielectric material 322 is different from the dielectric material 302. For example, the dielectric material 322 may be have a relatively high dielectric constant (e.g., κ=16), compared to the relatively low dielectric constant (e.g., κ=3.5) of the dielectric material 302. By having a relatively high dielectric constant in comparison to the dielectric constant of the dielectric material 302, the dielectric material 322 may provide a higher MOM capacitance without any change to the dimensions of the MOM capacitor 306, thereby also offering increased capacitance density compared to the MOM capacitor of FIG. 3A. The dielectric material 302 is used between the metal layers composing the MOM capacitor and also outside of the MOM capacitor (e.g., surrounding the metal lines 314), such that the regular routing parasitic capacitance is not increased between the homogeneous dielectric implementation of FIG. 3A and the hybrid dielectric implementation of FIG. 3B.

FIG. 3C is a cross-sectional view of metal layers 300C for a device, in accordance with certain aspects of the present disclosure. When compared with reference to metal layers 300B of FIG. 3B, metal layers 300C may be similar in construction. However, the dielectric material 322 in the metal layers 300C may not completely fill the spaces between the metal lines 316, 318, and 320 (i.e., the dielectric material 322 only partially fills the space between metal fingers of the MOM capacitor). For example, as illustrated in FIG. 3C, the dielectric material 322 may be U-shaped. The dielectric material 322 may have a high dielectric constant, but with this design, the effective dielectric constant for the combination of dielectric materials in the spaces between the metal lines 316, 318, 320 will be lower than having the higher κ dielectric material 322 completely filling these spaces, but the MOM capacitor will have a higher capacitance and an increased capacitance density compared to the MOM capacitor of FIG. 3A. For example, the effective dielectric constant may be 2 to 3 times higher than that of the dielectric material 302.

FIG. 3D is a cross-sectional view of metal layers 300D for a device, in accordance with certain aspects of the present disclosure. When compared with reference to metal layers 300B of FIG. 3B, metal layers 300D may be similar in construction. However, each space between metal lines 316, 318, and 320 may have a portion of dielectric material 322 disposed between two portions of dielectric material 302. The relative amounts of dielectric material 302 and dielectric material 322 in each space between metal lines 316, 318, and 322 may depend on the particular design (e.g., on the desired capacitance and manufacturing limitations). For example, there may be a larger portion of dielectric material 302 on one side of dielectric material 322 than on the other side of dielectric material 322. In certain aspects, there may be equal portions of dielectric material 302 on either side of dielectric material 322. With this design, the effective dielectric constant for the combination of dielectric materials in the spaces between the metal lines 316, 318, 320 will be lower than having the higher κ dielectric material 322 completely filling these spaces, but the MOM capacitor will have a higher capacitance and an increased capacitance density compared to the MOM capacitor of FIG. 3A.

FIG. 3E is a cross-sectional view of metal layers 300E for a device, in accordance with certain aspects of the present disclosure. When compared with reference to metal layers 300B of FIG. 3B, metal layers 300E may be similar in construction. However, each space between metal lines 316, 318, and 320 of the MOM capacitor may have a portion of dielectric material 302 disposed between two portions of dielectric material 322. The relative amounts of dielectric material 302 and dielectric material 322 in each space between metal lines 316, 318, and 322 may depend on the particular design (e.g., on the desired capacitance and manufacturing limitations). For example, there may be a larger portion of dielectric material 322 on one side of dielectric material 302 than on the other side of dielectric material 302. In certain aspects, there may be equal portions of dielectric material 322 on either side of dielectric material 302. Furthermore, the portions of dielectric material 322 may not have perfectly vertical edges. For example, the portion of dielectric material 302 may widen from top to bottom. As another example, the portion of dielectric material 302 may decrease in width from top to bottom. With this design, the effective dielectric constant for the combination of dielectric materials in the spaces between the metal lines 316, 318, 320 will be lower than having the higher κ dielectric material 322 completely filling these spaces, but the MOM capacitor will have a higher capacitance and an increased capacitance density compared to the MOM capacitor of FIG. 3A.

For certain aspects, the various structures of the dielectric material 322 and/or dielectric material 302 illustrated in FIGS. 3A-3E may be combined. For example, one metal layer of the MOM capacitor may have a dielectric material 322 that completely fills the spaces between the metal lines 316, 318, and 320, whereas another metal layer of the MOM capacitor may have U-shaped dielectric material. Furthermore, one metal layer of the MOM capacitor may have dielectric material 302 with a relatively low κ, whereas another metal layer of the MOM capacitor may have dielectric material 322 with a relatively high κ.

### Example Fabrication Processes

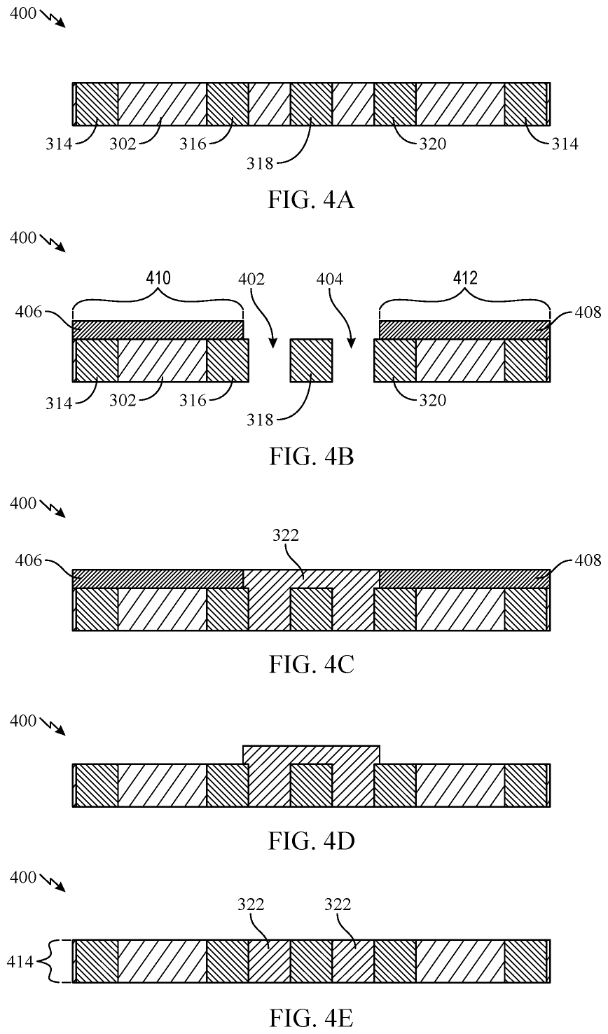

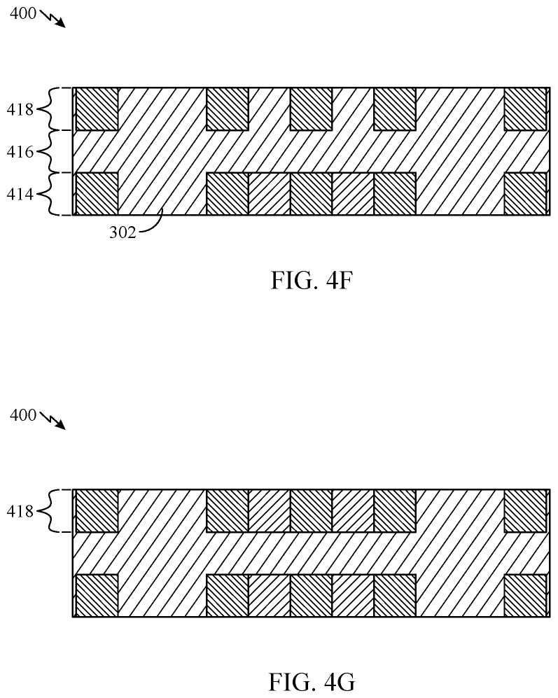

FIGS. 4A-4G illustrate example operations for fabricating metal layers for a semiconductor device, including a MOM capacitor with a hybrid dielectric, in accordance with certain aspects of the present disclosure. These operations may occur during BEOL fabrication of lower layers, for example.

FIG. 4A depicts a cross-sectional view of a portion of a workpiece 400, in accordance with certain aspects of the present disclosure. In FIG. 4A, the workpiece 400 may represent a lower metal layer (e.g., M1) of a semiconductor device. As shown, the workpiece 400 may be fabricated by forming a dielectric material 302 and metal lines 314, 316, 318, and 320. As depicted, the metal lines may be arranged such that a portion of the dielectric material 302 is between adjacent pairs of metal lines. Alternatively, there may be no dielectric material 302 between at least some adjacent pairs of metal lines. In certain aspects, the dielectric material 302 may have a relatively low dielectric constant (e.g., κ=3.5).

As shown in FIG. 4B, one or more portions of the workpiece 400 may be masked out (e.g., with a hard mask comprising silicon nitride). As shown, mask 406 and mask 408 may be formed above the dielectric material 302. Mask 406 may extend along a width 410 of the workpiece 400, which may cover routing metal lines and a metal line designated as an outer finger for a MOM capacitor. Likewise, mask 408 may extend along a width 412 of the workpiece 400, which may cover routing metal lines and a metal line designated as another outer finger for the MOM capacitor.

After masking, a portion of the dielectric material 302 of workpiece 400 may be removed (e.g., etched) to create gap 402 and gap 404. Gap 402 may separate metal line 316 and metal line 318, while gap 404 may separate metal line 318 and metal line 320. In certain aspects, gaps 402 and 404 may be the same size, while in other aspects, gaps 402 and 404 may be different sizes.

As portrayed in FIG. 4C, a dielectric material 322 with a relatively high dielectric constant (e.g., κ=16) may be deposited to fill gaps 402 and 404 of workpiece 400. Furthermore, in certain aspects, the dielectric material 322 may undergo chemical-mechanical planarization (CMP) to remove any excess dielectric material above the height of the masks 406, 408.

FIG. 4D depicts masks 406 and 408 being removed from (e.g., stripped off) workpiece 400.

FIG. 4E shows another CMP being performed on the dielectric material 322 above the height of the metal layer 414. After the CMP, the dielectric material 322 is generally flush with the top of metal layer 414.

FIG. 4F depicts another layer 416 of dielectric material 302 being formed (e.g., deposited) above metal layer 414 and another metal layer 418 being formed above the dielectric layer 416. Additionally, in certain aspects, similar processes as depicted in FIG. 4A may be performed on metal layer 418.

FIG. 4G depicts a cross-sectional view of the workpiece 400 after the processes depicted in FIGS. 4B-4E are repeated on metal layer 418. These operations may be repeated any desired number of times, which may depend on the number of metal layers in the MOM capacitor.

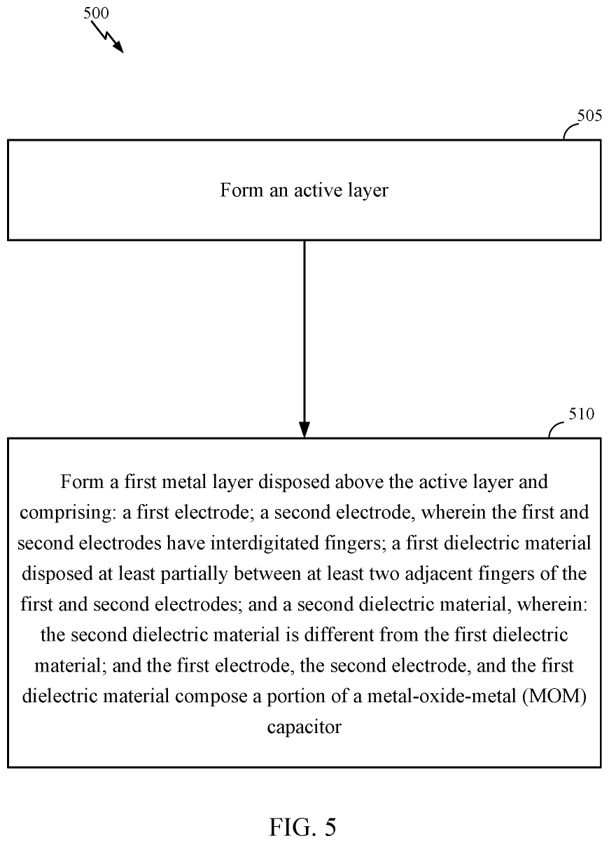

FIG. 5 is a flow diagram of example operations 500 for fabricating a semiconductor device (e.g., the semiconductor device 100 depicted in FIG. 1), in accordance with certain aspects of the present disclosure. The operations 500 may be performed by a semiconductor fabrication facility (also known as a “fab house” or foundry), for example.

The operations 500 may begin at block 505 with the fabrication facility forming an active layer. The active layer may include transistors (e.g., planar transistors, fin field-effect transistors (finFETs), and/or gate-all-around (GAA) transistors) and/or other semiconductor components (e.g., active electrical device 106).

At block 510, the fabrication facility may form a first metal layer (e.g., metal layer 414) above the active layer. The first metal layer may include a first electrode (e.g., element 12C) and a second electrode (e.g., element 14C), where the first and second electrodes have interdigitated fingers (e.g., metal fingers 20A and 20B). The first metal layer may also include a first dielectric material (e.g., dielectric material 322) disposed at least partially between at least two adjacent fingers of the first and second electrodes and a second dielectric material (e.g., dielectric material 302), which is different from the first dielectric material. The first electrode, the second electrode, and the first dielectric material compose a portion of a metal-oxide-metal (MOM) capacitor (e.g., MOM capacitor 10 or 306).

In certain aspects, a dielectric constant of the first dielectric material (e.g., dielectric material 322) is greater than a dielectric constant of the second dielectric material (e.g., dielectric material 302). In certain aspects, the dielectric constant of the first dielectric material is at least three times greater than the dielectric constant of the second dielectric material.

In certain aspects, the first electrode (e.g., element 12C) and/or the second electrode (e.g., element 14C) comprise cobalt or ruthenium. Alternatively, the first electrode and/or the second electrode may comprise any stable metal that does not implicate the use of a barrier metal. These stable metals include tungsten, molybdenum, ruthenium, palladium, osmium, iridium, and platinum.

According to certain aspects, the first dielectric material (e.g., dielectric material 322) completely fills a space (e.g., gap 402) in the first metal layer (e.g., metal layer 414) between the at least two adjacent fingers (e.g., metal lines 316 and 318) of the first and second electrodes. According to other aspects, a space in the first metal layer between the at least two adjacent fingers of the first and second electrodes is occupied by the first dielectric material and the second dielectric material (e.g., as shown in FIGS. 3C-3E). In certain aspects, the space in the first metal layer between the at least two adjacent fingers of the first and second electrodes is occupied by a region comprising the first dielectric material disposed between two regions comprising the second dielectric material (e.g., as shown in FIG. 3D). In other aspects, the space in the first metal layer between the at least two adjacent fingers of the first and second electrodes is occupied by a region comprising the second dielectric material disposed between two regions comprising the first dielectric material (e.g., as illustrated in FIG. 3E). In certain aspects, the space in the first metal layer between the at least two adjacent fingers of the first and second electrodes is occupied by a U-shaped region comprising the first dielectric material and wrapped around another region comprising the second dielectric material (e.g., as depicted in FIG. 3C).

In certain aspects, the first metal layer further comprises one or more metal lines (e.g., metal lines 314). In this case, the second dielectric material (e.g., dielectric material 302) may be disposed between the one or more metal lines and at least one of the first electrode or the second electrode. In certain aspects, the first electrode (e.g., element 12C), the second electrode (e.g., element 14C), and the one or more metal lines (e.g., metal line 314) comprise cobalt, ruthenium, tungsten, molybdenum, palladium, osmium, iridium, or platinum.

In certain aspects, the operations 500 further comprise forming a dielectric layer (e.g., dielectric layer 416) above the first metal layer (e.g., metal layer 414). In this case, the dielectric layer may comprise the second dielectric material (e.g., dielectric material 302). In certain aspects, the operations 500 further comprise forming a second metal layer (e.g., metal layer 418) above the dielectric layer. The second metal layer may include a third electrode (e.g., element 12B) and a fourth electrode (e.g., element 14B), where the third and fourth electrodes have interdigitated fingers (e.g., metal fingers 20A and 20B). The second metal layer may also include a third dielectric material (e.g., dielectric material 322) disposed at least partially between at least two adjacent fingers of the third and fourth electrodes, where the third dielectric material is different from at least one of the first dielectric material or the second dielectric material. In this case, the MOM capacitor may include the first electrode, the second electrode, the third electrode, the fourth electrode, the first dielectric material, the third dielectric material, and at least a portion of the dielectric layer between the first and second electrodes of the first metal layer and the third and fourth electrodes of the second metal layer. In certain aspects, the first dielectric material is the same as the third dielectric material, whereas in other aspects, the first and third dielectric materials are different. In certain aspects, the third dielectric material completely fills a space in the second metal layer between the at least two adjacent fingers of the third and fourth electrodes (e.g., as shown in FIG. 4G). In other aspects, a space in the second metal layer between the at least two adjacent fingers of the third and fourth electrodes is occupied by the second dielectric material and the third dielectric material. In this case, the space in the second metal layer between the at least two adjacent fingers of the third and fourth electrodes may be occupied by a region comprising the second dielectric material disposed between two regions comprising the third dielectric material, or as an alternative, the space in the second metal layer between the at least two adjacent fingers of the third and fourth electrodes may be occupied by a region comprising the third dielectric material disposed between two regions comprising the second dielectric material. In certain aspects, the space in the second metal layer between the at least two adjacent fingers of the third and fourth electrodes is occupied by a U-shaped region comprising the third dielectric material and wrapped around another region comprising the second dielectric material.

In certain aspects, at least one of the first metal layer or the second metal layer lacks a barrier metal.

In certain aspects, at least one of the first metal layer or the second metal layer comprises cobalt, ruthenium, tungsten, molybdenum, palladium, osmium, iridium, or platinum. In this case, one or more metal layers disposed above the first metal layer and the second metal layer may comprise copper.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes, and variations may be made in the arrangement, operation, and details of the methods and apparatus described above without departing from the scope of the claims.

1. A semiconductor device comprising:
an active layer; and
a first metal layer disposed above the active layer and comprising:
a first electrode;
a second electrode, wherein the first and second electrodes have interdigitated fingers;
a first dielectric material disposed at least partially between at least two adjacent fingers of the first and second electrodes; and
a second dielectric material, wherein:
the second dielectric material is different from the first dielectric material; and
the first electrode, the second electrode, and the first dielectric material compose a portion of a metal-oxide-metal (MOM) capacitor.

2. The semiconductor device of claim 1, wherein a dielectric constant of the first dielectric material is greater than a dielectric constant of the second dielectric material.

3. The semiconductor device of claim 2, wherein the dielectric constant of the first dielectric material is at least three times greater than the dielectric constant of the second dielectric material.

4. The semiconductor device of claim 1, wherein the first electrode and the second electrode comprise cobalt, ruthenium, tungsten, molybdenum, palladium, osmium, iridium, or platinum.

5. The semiconductor device of claim 1, wherein the first dielectric material completely fills a space in the first metal layer between the at least two adjacent fingers of the first and second electrodes.

6. The semiconductor device of claim 1, wherein a space in the first metal layer between the at least two adjacent fingers of the first and second electrodes is occupied by the first dielectric material and the second dielectric material.

7. The semiconductor device of claim 6, wherein the space in the first metal layer between the at least two adjacent fingers of the first and second electrodes is occupied by a region comprising the first dielectric material disposed between two regions comprising the second dielectric material.

8. The semiconductor device of claim 6, wherein the space in the first metal layer between the at least two adjacent fingers of the first and second electrodes is occupied by a region comprising the second dielectric material disposed between two regions comprising the first dielectric material.

9. The semiconductor device of claim 6, wherein the space in the first metal layer between the at least two adjacent fingers of the first and second electrodes is occupied by a U-shaped region comprising the first dielectric material and wrapped around another region comprising the second dielectric material.

10. The semiconductor device of claim 1, wherein:
the first metal layer further comprises one or more metal lines;
the second dielectric material is disposed between the one or more metal lines and at least one of the first electrode or the second electrode; and
the first electrode, the second electrode, and the one or more metal lines comprise cobalt, ruthenium, tungsten, molybdenum, palladium, osmium, iridium, or platinum.

11. The semiconductor device of claim 1, wherein the first metal layer lacks a barrier metal.

12. The semiconductor device of claim 1, further comprising:
a dielectric layer disposed above the first metal layer, wherein the dielectric layer comprises the second dielectric material; and
a second metal layer disposed above the dielectric layer and comprising:
a third electrode;
a fourth electrode, wherein the third and fourth electrodes have interdigitated fingers;
a third dielectric material disposed at least partially between at least two adjacent fingers of the third and fourth electrodes, wherein:
the third dielectric material is different from at least one of the first dielectric material or the second dielectric material; and
the MOM capacitor comprises the first electrode, the second electrode, the third electrode, the fourth electrode, the first dielectric material, the third dielectric material, and at least a portion of the dielectric layer between the first and second electrodes of the first metal layer and the third and fourth electrodes of the second metal layer.

13. The semiconductor device of claim 12, wherein the first dielectric material is the same as the third dielectric material.

14. The semiconductor device of claim 12, wherein the third dielectric material completely fills a space in the second metal layer between the at least two adjacent fingers of the third and fourth electrodes.

15. The semiconductor device of claim 12, wherein a space in the second metal layer between the at least two adjacent fingers of the third and fourth electrodes is occupied by the second dielectric material and the third dielectric material.

16. The semiconductor device of claim 15, wherein the space in the second metal layer between the at least two adjacent fingers of the third and fourth electrodes is occupied by a region comprising the second dielectric material disposed between two regions comprising the third dielectric material.

17. The semiconductor device of claim 15, wherein the space in the second metal layer between the at least two adjacent fingers of the third and fourth electrodes is occupied by a region comprising the third dielectric material disposed between two regions comprising the second dielectric material.

18. The semiconductor device of claim 15, wherein the space in the second metal layer between the at least two adjacent fingers of the third and fourth electrodes is occupied by a U-shaped region comprising the third dielectric material and wrapped around another region comprising the second dielectric material.

19. The semiconductor device of claim 12, wherein:
at least one of the first metal layer or the second metal layer comprises cobalt, ruthenium, tungsten, molybdenum, palladium, osmium, iridium, or platinum; and
one or more metal layers disposed above the first metal layer and the second metal layer comprise copper.

20. A method of fabricating a semiconductor device, the method comprising:
forming an active layer; and
forming a first metal layer above the active layer, the first metal layer comprising:
a first electrode;
a second electrode, wherein the first and second electrodes have interdigitated fingers;
a first dielectric material disposed at least partially between at least two adjacent fingers of the first and second electrodes; and
a second dielectric material, wherein:
the second dielectric material is different from the first dielectric material; and
the first electrode, the second electrode, and the first dielectric material compose a portion of a metal-oxide-metal (MOM) capacitor.
